(19) United States
(12) Patent Application Publication
(10) Pub. No.: US 2024/0063647 A1
(43) Pub. Date: Feb. 22, 2024

(54) Battery Management Apparatus and Method

(71) Applicant: LG Energy Solution, Ltd., Seoul (KR)

(72) Inventors: Seok Hyeong Ham, Daejeon (KR); Duk You Kim, Daejeon (KR)

(73) Assignee: LG Energy Solution, Ltd., Seoul (KR)

(21) Appl. No.: 18/270,297

(22) PCT Filed: Jul. 27, 2022
(86) PCT No.: PCT/KR2022/011056

§ 371 Date: Jun. 29, 2023

(30) Foreign Application Priority Data
Aug. 3, 2021 (KR) 10-2021-0102179

(51) Int. Cl. H02J 7/00; G01R 31/3835; G01R 31/389; G01R 31/396

(52) U.S. Cl. CPC H02J 7/00712; H02J 7/0047; G01R 31/3835; G01R 31/389; G01R 31/396

(57) ABSTRACT

A battery management apparatus according to an embodiment disclosed herein includes a power source unit including a plurality of power sources, a measurement unit configured to measure a first voltage by applying a first power source among the plurality of power sources to a battery cell and to measure a second voltage by applying a second power source among the plurality of power sources to the battery cell, and a calculating unit configured to calculate a voltage of the battery cell based on the first voltage and the second voltage.

### CROSS-REFERENCE TO RELATED APPLICATION

The present application is a national phase entry under 35 U.S.C. § 371 of International Application No. PCT/KR2022/011056 filed on Jul. 27, 2022 which claims priority to Korean Patent Application No. 10-2021-0102179 filed on Aug. 3, 2021 in the Republic of Korea, the disclosures of which are incorporated herein by reference.

### TECHNICAL FIELD

Embodiments disclosed herein relate to a battery management apparatus and method.

### BACKGROUND ART

A secondary battery is generally used as a battery pack including a battery module where a plurality of battery cells are connected to one another in series and/or in parallel. Battery packs may be managed and controlled by a battery management system in terms of their states and operations.

Today, with an increasing demand for such secondary batteries, the importance of a battery management system (BMS) that manages a battery pack or a battery module is also increasing. Generally, the BMS essentially includes a Battery Monitoring Integrated Circuit (BMIC) circuit that measures a voltage and performs balancing between battery cells, etc.

A voltage of a battery cell may be simply measured by using the BMIC circuit, but a voltage error may occur for battery cells provided at opposite ends of a battery module due to a voltage drop caused by a current required for driving of the BMIC circuit and an internal resistance of a battery cell.

As such, since the voltages of the battery cells at the opposite ends of the battery module are measured lower than those of other battery cells, a separate voltage measuring apparatus is required to correct the error.

### SUMMARY

### Technical Problem

Embodiments disclosed herein aims to provide a battery management apparatus and method in which an error caused by an internal resistance may be automatically corrected without a separate apparatus in voltage measurement for a battery cell.

Technical problems of the embodiments disclosed herein are not limited to the above-described technical problems, and other unmentioned technical problems would be clearly understood by one of ordinary skill in the art from the following description.

### Technical Solution

A battery management apparatus according to an embodiment disclosed herein includes a plurality of power sources, a controller and memory having programmed thereon instructions that, when executed, are configured to cause the controller to receive a first measurement of a first voltage of a battery cell measured while a first power source among the plurality of power sources is applied to the battery cell and a second measurement of a second voltage of the battery cell measured while a second power source among the plurality of power sources is applied to the battery cell, and calculate a voltage of the battery cell based on the first voltage and the second voltage.

According to an embodiment, the instructions are further configured to cause the controller to calculate the voltage of the battery cell based on a difference between the first voltage and the second voltage.

According to an embodiment, the instructions are further configured to cause the controller to calculate an internal resistance of the battery cell based on the first voltage and the second voltage.

According to an embodiment, the instructions are further configured to cause the controller to correct the voltage of the battery cell based on the internal resistance of the battery cell.

According to an embodiment, the battery cell is provided in one end of a battery module.

According to an embodiment, the plurality of power sources may be driving power sources of a Battery Monitoring Integrated Circuit (BMIC) that manages the battery cell.

A battery management method according to an embodiment disclosed herein includes measuring a first voltage by applying a first power source among a plurality of power sources to a battery cell, measuring a second voltage by applying a second power source, which is different from the first power source, among the plurality of power sources, to the battery cell, and calculating a voltage of the battery cell based on the first voltage and the second voltage.

According to an embodiment, calculating the voltage of the battery cell is based on a difference between the first voltage and the second voltage.

According to an embodiment, calculating the voltage of the battery cell may include calculating an internal resistance of the battery cell based on the first voltage and the second voltage.

According to an embodiment, calculating the voltage of the battery cell may include correcting the voltage of the battery cell based on the internal resistance of the battery cell.

### Advantageous Effects

A battery management apparatus and method according to an embodiment disclosed herein may automatically correct an error caused by an internal resistance without a separate apparatus in voltage measurement for a battery cell.

### BRIEF DESCRIPTION OF THE DRAWINGS

FIG. 1 schematically illustrates a configuration of a battery control system including a battery management apparatus according to an embodiment disclosed herein.

FIG. 2 is a block diagram illustrating a structure of a battery management apparatus, according to an embodiment disclosed herein.

FIG. 3 is a view of conventional battery module and battery management apparatus.

FIG. 4 is a view of a battery module and a battery management apparatus according to an embodiment disclosed herein.

FIG. 5 is a flowchart illustrating a battery management method according to an embodiment disclosed herein.

FIG. 6 is a block diagram showing a hardware configuration of a computing system for performing a battery management method according to an embodiment disclosed herein.

### DETAILED DESCRIPTION

Hereinafter, various embodiments disclosed herein will be described in detail with reference to the accompanying drawings. In this document, identical reference numerals will be used for identical components in the drawings, and the identical components will not be redundantly described.

For various embodiments disclosed herein, specific structural or functional descriptions are only exemplified for the purpose of describing the embodiments, and various embodiments disclosed herein may be implemented in various forms, and should not be construed as being limited to the embodiments described herein.

As used in various embodiments, the terms “1st, “2nd”, “first”, “second”, or the like may modify various components regardless of importance, and do not limit the components. For example, a first component may be named as a second component without departing from the right scope of an embodiment disclosed herein, and similarly, the second component may be named as the first component.

Terms used in the present document are used for only describing a specific exemplary embodiment of the disclosure and may not have an intention to limit the scope of other exemplary embodiments of the disclosure. It is to be understood that the singular forms include plural references unless the context clearly dictates otherwise.

All terms including technical and scientific terms used herein have the same meaning as commonly understood by one of ordinary skill in the art to which the embodiments disclosed herein belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein. In some cases, the terms defined herein may be interpreted to exclude embodiments disclosed herein.

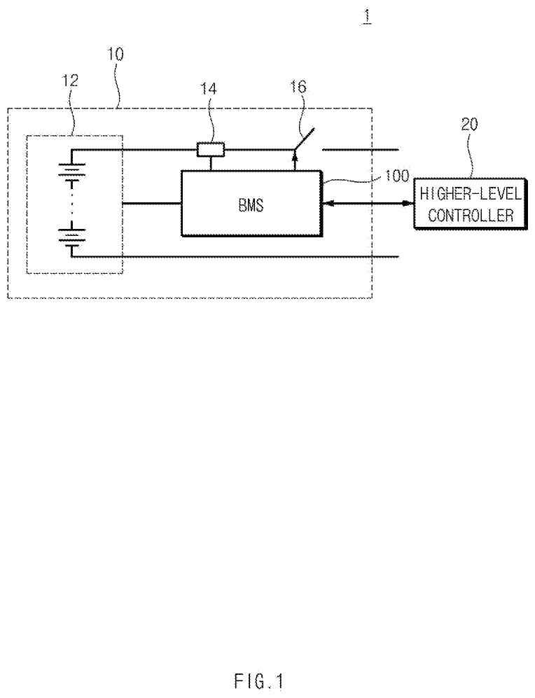

FIG. 1 schematically illustrates a configuration of a battery control system including a battery management apparatus according to an embodiment disclosed herein.

Referring to FIG. 1, a battery control system 1 may include a battery pack 10 and a higher-level controller 20. The battery pack 10 may include a battery module 12, a sensor 14, a switching unit 16, and a battery management apparatus (or a battery management system (BMS)) 100. The battery pack 10 may include the battery module 12, the sensor 14, the switching unit 16, and the battery management apparatus 100 provided in plural. The battery pack 10 may be connected in series or in parallel to communicate with the higher-level controller 20 provided outside.

The battery module 12 may include one or more chargeable/dischargeable battery cells. In this case, the battery module 12 may be connected in series or in parallel. The sensor 14 may detect current flowing in the battery pack 10. In this case, a detected signal of current may be transmitted to the battery management apparatus 100. The switching unit 16 may be connected in series to a (+) terminal side and a (−) terminal side of the battery module 12 to control the charging/discharging current flow of the battery module 12. For example, the switching unit 16 may use at least one switch, relay, magnetic contactor, etc., according to the specifications of the battery pack 10.

The battery management apparatus 100 may monitor the voltage, current, temperature, etc., of the battery pack 10 to perform control and management to prevent overcharging and over-discharging, etc., and may be, for example, a BMS of a battery pack.

The battery management apparatus 100, which is an interface for receiving measurement values of various parameter values, may include a plurality of terminals and a circuit, etc., connected to the terminals to process received values. The battery management apparatus 100 may control ON/OFF of the switching unit 16, e.g., a switch, a relay, a contactor, etc., and may be connected to the plurality of battery modules 12 to monitor the state of battery cells.

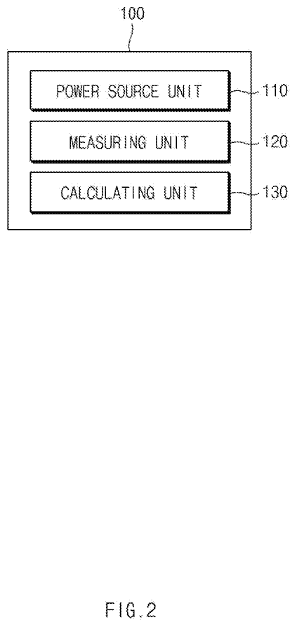

Meanwhile, the battery management apparatus 100 disclosed herein may measure a voltage of each battery cell included in the battery module 12 through a BMIC. The battery management apparatus 100 may measure a voltage of a battery cell by applying a plurality of BMIC driving currents and calculate an internal resistance of the battery cell based on the measured voltage. In this way, the battery management apparatus 100 may correct a voltage measurement error for a battery cell, caused by an internal resistance of the battery cell. The configuration of the battery management apparatus 100 will be described in detail with reference to FIG. 2.

The higher-level controller 20 may transmit various control signals regarding the battery module 12 to the battery management apparatus 100. Thus, the battery management apparatus 100 may also be controlled in terms of an operation thereof based on a signal applied from the higher-level controller 20. Meanwhile, the battery cell according to the present disclosure may be included in the battery module 12 used for an electric vehicle. However, the battery pack 10 of FIG. 1 is not limited to such a purpose, and for example, a battery rack of an energy storage system (ESS) may be included in place of the battery pack 10 of FIG. 1.

FIG. 2 is a block diagram illustrating a structure of a battery management apparatus, according to an embodiment disclosed herein.

Referring to FIG. 2, the battery management apparatus 100 according to an embodiment disclosed herein may include a power source unit 110, a measuring unit 120, and a calculating unit 130.

The power source unit 110 may include a plurality of power sources. In this case, the plurality of power sources included in the power source unit 110 may be driving power sources of a BMIC circuit that manages a battery cell. For example, the power source unit 110 may control the plurality of power sources through a switching circuit.

The measuring unit 120 may measure a voltage of a battery cell by applying a power source of the power source unit 110 to the battery cell. For example, the measuring unit 120 may measure a first voltage by applying a first power source among the plurality of power sources to the battery cell and measure a second voltage by applying a second power source among the plurality of power sources to the battery cell. The battery cell may be a battery cell provided in one end of a battery module.

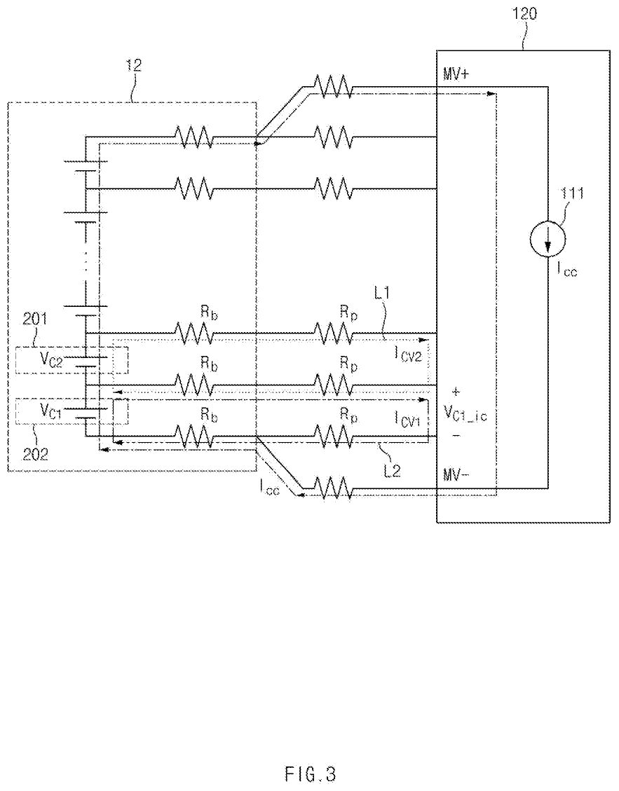

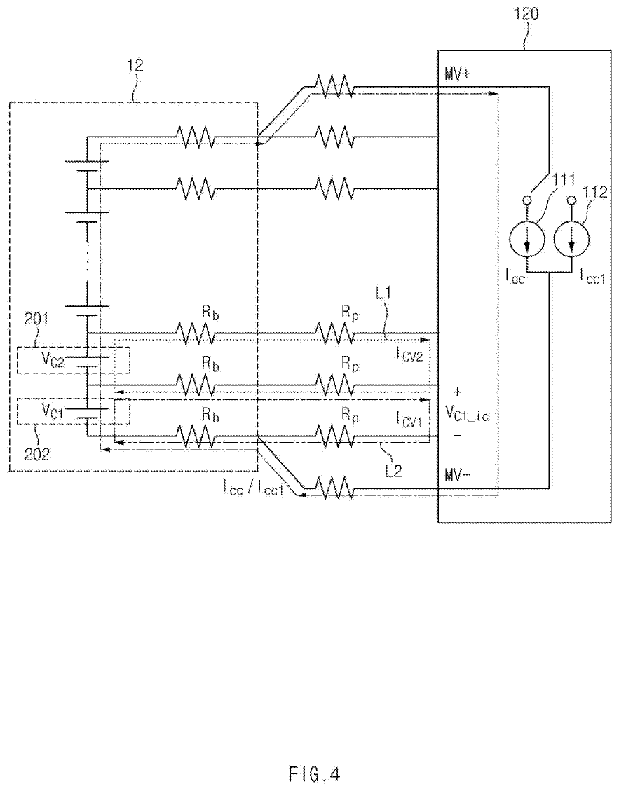

The calculating unit 130 may calculate a voltage of the battery cell based on the first voltage and the second voltage respectively measured by respectively applying the first power source and the second power source to the battery cell. For example, the calculating unit 130 may calculate the voltage of the battery cell based on a difference between the first voltage and the second voltage. In this case, the calculating unit 130 may calculate an internal resistance of the battery cell based on the first voltage and the second voltage measured for the battery cell. In this way, the calculating unit 130 may correct the voltage of the battery cell based on the internal resistance of the battery cell. A detailed voltage calculation method of the calculating unit 130 will be described with reference to FIGS. 3 and 4.

As such, the battery management apparatus 100 according to an embodiment disclosed herein may automatically correct an error caused by an internal resistance without a separate apparatus in voltage measurement for the battery cell.

FIG. 3 is a view of conventional battery module and battery management apparatus. FIG. 4 is a view of a battery module and a battery management apparatus according to an embodiment disclosed herein.

Referring to FIG. 3, in the conventional battery management apparatus, in voltage measurement for a battery cell 202 provided in one end of a battery module 12, a strong voltage drop occurs due to a driving current I_{cc} of a BMIC supplied from a power source 111 and an internal resistance component R_{b} of the battery cell 202. In this case, because of I_{cc}>>I_{CVn}, the other battery cells are not affected by the voltage drop. Meanwhile, the internal resistance R_{b} of the battery cell is difficult to directly measure. As such, according to the conventional battery management apparatus, for the battery cell 202 provided in one end of the battery module 12, a voltage of the battery cell 202 is measured low at all times due to the internal resistance R_{b} of the battery cell 202, and correction thereof requires re-measurement using a separate voltage measurement apparatus.

Referring to FIG. 4, the battery management apparatus 100 according to an embodiment disclosed herein may be selectively supplied with a driving current of a BMIC from a first power source 111 and a second power source 112. That is, in the battery management apparatus 100 according to an embodiment disclosed herein, a BMIC driving current based on the first power source 111 may be applied and then a first voltage of the battery cell 202 may be measured through the measuring unit 120, and a BMIC driving current based on the second power source 112 may be applied and then a second voltage of the battery cell 202 may be measured through the measuring unit 120.

Moreover, the battery management apparatus 100 according to an embodiment disclosed herein may calculate the internal resistance R_{b} of the battery cell based on a difference between the first voltage and the second voltage measured in this way. The battery management apparatus 100 may correct a voltage error of the battery cell 202 by using the calculated internal resistance R_{b} and driving currents I_{cc} and I_{cc1} of the BMIC. The other battery cells such as a battery cell 201 are not affected by a voltage drop caused by a driving current of the BMIC, not requiring separate correction.

More specifically, the calculating unit 130 of the battery management apparatus 100 according to an embodiment disclosed herein may calculate the voltage of the battery cell 202 according to the following equations. In this case, when a BMIC driving current I_{cc} based on the first power source 111 is applied, the voltage of the battery cell 202 may be expressed according to the Kirchhoff s voltage law as below (L2).

V_{C1}=V_{C1}−2(R_{b}−Rₚ)I_{CV1}−R_{b}I_{cc}≈V_{C1}−R_{b}I_{cc} [Equation 1]

(I_{cc}>>I_{CV1})

In addition, when a BMIC driving current I c a based on the second power source 112 is applied, the voltage of the battery cell 202 may be expressed as below.

V_{C1}_{_{ic1}}=V_{C1}−2(R_{b}+Rₚ)I_{CV1}−R_{b}I_{cc1}≈V_{C1}−R_{b}I_{cc1} [Equation 2]

(I_{cc1}>>I_{CV1})
V_{cn}: a voltage of a battery cell,
V_{Cn_ic}: a voltage of a battery cell measured in a BMIC
R_{b}: an internal resistance of a battery cell
Rₚ: a resistance of a connection path between a BMIC and a battery cell
I_{cc}, I_{cc1}: a current flowing to a pin in measurement of a voltage of a battery cell
I_{cc}, I_{cc1}: a driving current of a BMIC

As such, the calculating unit 130 of the battery management apparatus 100 according to an embodiment disclosed herein may calculate the internal resistance R_{b} of a battery cell and a voltage V_{C1} of the battery cell by simultaneously calculating Equation 1 and Equation 2. That is, it is possible to correct the voltage V_{cn_ic} of the battery cell measured by using the driving currents I_{cc} and I_{cc1} of the BMIC and the calculated internal resistance R_{b} of the battery cell.

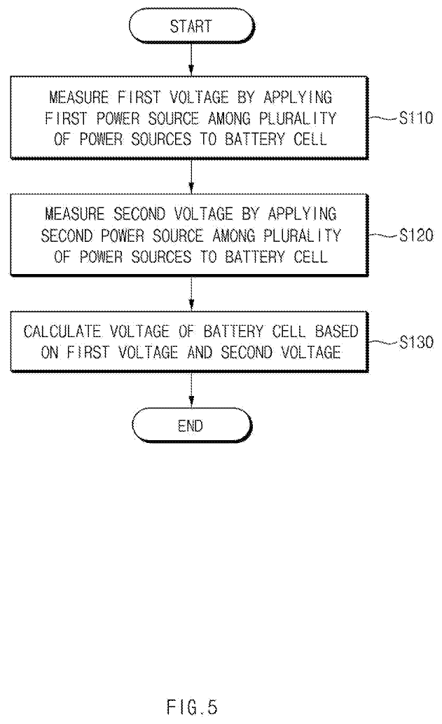

FIG. 5 is a flowchart illustrating a battery management method according to an embodiment disclosed herein.

Referring to FIG. 5, a battery management method according to an embodiment disclosed herein may measure a first voltage by applying a first power source among a plurality of power sources to a battery cell, in operation S110. A second voltage may be measured by applying a second power source among the plurality of power sources to the battery cell, in operation S120. The battery cell may be a battery cell provided in one end of a battery module. The plurality of power sources may be driving power sources of a BMIC circuit that manages the battery cell. For example, the plurality of power sources may be controlled through a switching circuit.

Next, the voltage of the battery cell may be calculated based on the first voltage and the second voltage, in operation S130. For example, the voltage of the battery cell may be calculated based on a difference between the first voltage and the second voltage. In this case, an internal resistance of the battery cell may be calculated based on the first voltage and the second voltage measured for the battery cell. In this way, in operation S130, the voltage of the battery cell may be corrected based on the internal resistance of the battery cell.

As such, the battery management method according to an embodiment disclosed herein may automatically correct an error caused by an internal resistance without a separate apparatus in voltage measurement for the battery cell.

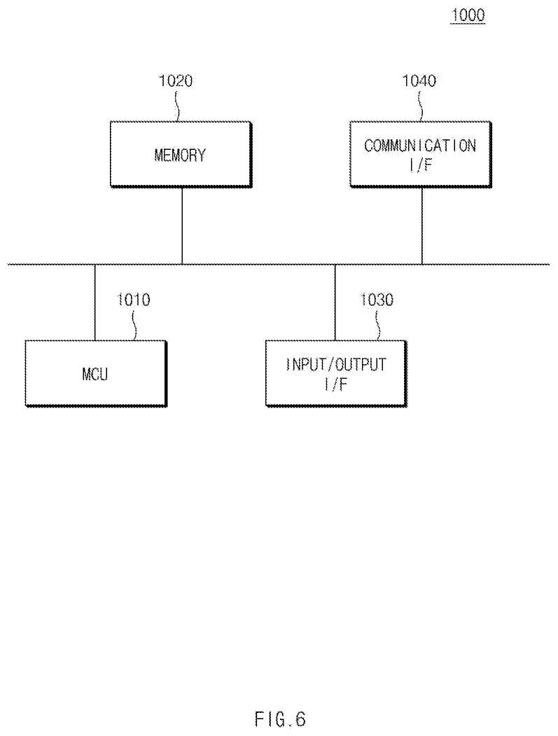

FIG. 6 is a block diagram showing a hardware configuration of a computing system for performing a battery management method according to an embodiment disclosed herein.

Referring to FIG. 6, a computing system 1000 according to an embodiment disclosed herein may include a Main Control Unit (MCU) 1010, a memory 1020, an input/output interface (I/F) 1030, and a communication I/F 1040.

The MCU 1010 may be a processor that executes various programs (e.g., a program for measuring a voltage of a battery, a program for calculating an internal resistance and a voltage of a battery cell, etc.) stored in the memory 1020, processes various data including voltage, internal resistance, etc., of a battery cell through these programs, and performs the above-described functions of the battery management apparatus 100 shown in FIG. 2.

The memory 1020 may store various programs regarding voltage measurement, internal resistance and voltage calculation, etc., for a battery cell. Moreover, the memory 1020 may store various data such as a voltage, an internal resistance, etc., of the battery cell.

The memory 1020 may be provided in plural, depending on a need. The memory 1020 may be volatile memory or non-volatile memory. For the memory 1020 as the volatile memory, random access memory (RAM), dynamic RAM (DRAM), static RAM (SRAM), etc., may be used. For the memory 1020 as the nonvolatile memory, read only memory (ROM), programmable ROM (PROM), electrically alterable ROM (EAROM), erasable PROM (EPROM), electrically erasable PROM (EEPROM), flash memory, etc., may be used. The above-listed examples of the memory 1020 are merely examples and are not limited thereto.

The input/output I/F 1030 may provide an interface for transmitting and receiving data by connecting an input device (not shown) such as a keyboard, a mouse, a touch panel, etc., and an output device such as a display (not shown), etc., to the MCU 1010.

The communication I/F 1040, which is a component capable of transmitting and receiving various data to and from a server, may be various devices capable of supporting wired or wireless communication. For example, a program for voltage measurement or internal resistance and voltage calculation for a battery cell, various data, etc., may be transmitted and received to and from a separately provided external server through the communication I/F 1040.

As such, a computer program according to an embodiment disclosed herein may be recorded in the memory 1020 and processed by the MCU 1010, thus being implemented as a module that performs functions shown in FIG. 2.

Even though all components constituting an embodiment disclosed herein have been described above as being combined into one or operating in combination, the embodiments disclosed herein are not necessarily limited to the embodiments. That is, within the object scope of the embodiments disclosed herein, all the components may operate by being selectively combined into one or more.

Moreover, terms such as “include”, “constitute” or “have” described above may mean that the corresponding component may be inherent unless otherwise stated, and thus should be construed as further including other components rather than excluding other components. All terms including technical or scientific terms have the same meanings as those generally understood by those of ordinary skill in the art to which the embodiments disclosed herein pertain, unless defined otherwise. The terms used generally like terms defined in dictionaries should be interpreted as having meanings that are the same as the contextual meanings of the relevant technology and should not be interpreted as having ideal or excessively formal meanings unless they are clearly defined in the present document.

The above description is merely illustrative of the technical idea of the present disclosure, and various modifications and variations will be possible without departing from the essential characteristics of embodiments of the present disclosure by those of ordinary skill in the art to which the embodiments disclosed herein pertains. Therefore, the embodiments disclosed herein are intended for description rather than limitation of the technical spirit of the embodiments disclosed herein and the scope of the technical spirit of the present disclosure is not limited by these embodiments disclosed herein. The protection scope of the technical spirit disclosed herein should be interpreted by the following claims, and all technical spirits within the same range should be understood to be included in the range of the present document.

1. A battery management apparatus comprising:
a plurality of power sources;
a controller;
memory having programmed thereon instructions that, when executed, are configured to cause the controller to:
receive a first measurement of a first voltage of a battery cell measured while a first power source among the plurality of power sources is applied to the battery cell and a second measurement of a second voltage of the battery cell measured while a second power source among the plurality of power sources is applied to the battery cell; and
calculate a voltage of the battery cell based on the first voltage and the second voltage.

2. The battery management apparatus of claim 1, wherein the instructions are further configured to cause the controller to calculate the voltage of the battery cell based on a difference between the first voltage and the second voltage.

3. The battery management apparatus of claim 2, wherein the instructions are further configured to cause the controller to calculate an internal resistance of the battery cell based on the first voltage and the second voltage.

4. The battery management apparatus of claim 3, wherein the instructions are further configured to cause the controller to correct the voltage of the battery cell based on the internal resistance of the battery cell.

5. The battery management apparatus of claim 1, wherein the battery cell provided in one end of a battery module.

6. The battery management apparatus of claim 1, wherein the plurality of power sources are driving power sources of a Battery Monitoring Integrated Circuit (BMIC) that manages the battery cell.

7. A battery management method comprising:
measuring a first voltage by applying a first power source among a plurality of power sources to a battery cell;
measuring a second voltage by applying a second power source, which is different from the first power source, among the plurality of power sources, to the battery cell; and
calculating a voltage of the battery cell based on the first voltage and the second voltage.

8. The battery management method of claim 7, wherein calculating the voltage of the battery cell is based on a difference between the first voltage and the second voltage.

9. The battery management method of claim 8, wherein calculating of the voltage of the battery cell comprises calculating an internal resistance of the battery cell based on the first voltage and the second voltage.

10. The battery management method of claim 9, wherein calculating the voltage of the battery cell comprises correcting the voltage of the battery cell based on the internal resistance of the battery cell.
